(19) United States
(12) Patent Application Publication
(10) Pub. No.: US 2008/0093641 A1
(43) Pub. Date: Apr. 24, 2008

(54) METHOD OF MANUFACTURING A MULTI-PATH LATERAL HIGH-VOLTAGE FIELD EFFECT TRANSISTOR

(76) Inventors: Adrianus Willem Ludikhuize, Valkenswaard (NL); Inesz Marycka Weijland, Malden (NL); Joan Wichard Strijker, Wijchen (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(21) Appl. No.: 11/742,375

(22) Filed: Apr. 30, 2007

(30) Foreign Application Priority Data
Oct. 22, 2006 (IB) WO/IB006/0539

(51) Int. Cl. H01L 29/94; H01L 21/22

(52) U.S. Cl. 257/289; 257/343; 438/569; 257/E21.135; 257/E29.345

(57) ABSTRACT

High-Voltage Lateral MOSFET and Lateral Double-diffused MOS (LDMOS) for HV power applications with multiple paths for conduction in the drain extension and methods of fabrication are described.

### CROSS-REFERENCE TO RELATED APPLICATIONS

The present application is a continuation of International Patent Application WO/IB2006/0539 to Adrianus W. Ludikhuize, et al., filed on Oct. 22, 2006, which in turn claims priority from European Patent Application (NXP Docket Number PH002312EP1) filed on Nov. 2, 2005. The present application is also related to U.S. Patent Application (NXP Docket Number PH008356) filed on even dated herewith. Priority is hereby claimed under under 35 U.S.C. §365(c) and 35 U.S.C. §120 from the referenced International Patent Application. The disclosures of these cross-referenced patent applications are specifically incorporated herein by reference.

### BACKGROUND

Power devices are electronic components designed for use in the comparatively high voltage and high current applications. These devices may be implemented in widely varying applications to include lighting, automotive, consumer and appliance applications. Power devices include semiconductor devices that are adapted to function at high voltage and high current. One type of semiconductor device that is often implemented in power devices is power lateral double-diffused metal-oxide-semiconductor (LDMOS) field-effect-transistor (FET) device, referred to herein as a power LDMOS device. Another type of semiconductor device that is often implemented in such applications is a lateral High-Voltage Lateral MOSFET (HVFET).

As power technologies develop, power applications require power LDMOS devices to be cheaper and smaller in physical size. Often, the demands on the reduced size do not relax the power requirements; rather the power requirements may be the same or even increased. Moreover, there is a need to provide these devices with a comparatively high breakdown voltage (V_{BD}), depending on the application. One LDMOS device adapted to provide the high breakdown voltage requirement combined with good on-state properties includes a reduced surface field (RESURF) structure. A power LDMOS or HVFET device having a RESURF structure comprises a first semiconductor region, which serves as a RESURF drift region, having one conductivity type; and a second semiconductor region, which serves as a charge balance region, having a different conductivity type. Moreover, the LDMOS and HVFETs may have one or a plurality of channels in the drift region of the device.

One known method for making LDMOS and HVFETs includes growing multiple epitaxial layers of alternating polarity to provide a plurality of channels. However, for proper RESURF operation, ion implantation of dopant charges is beneficial to effect proper doping of the pn-layers.

Another known method for making LDMOS and HVFETs with one or more conduction channels in parallel in the drift-region includes forming conduction channels of a second conductivity type in the extended drain by successive deep implantation of a dopant of a first conductivity type in a deep well or in an epitaxial layer of a second conductivity type so as to form a plurality of buried layers disposed at different vertical depths. The deep well or epitaxial layer of a second conductivity type is formed in or on a substrate of a first conductivity type. A second epitaxial layer of the second conduction type may be formed on the deep well or first epitaxial layer and the deep implant of the first conductivity type is repeated to form a second plurality of buried layers in stacked parallel relationship to the first plurality of buried layers. The stacked p-n layers in the extended drain form a drift region of the LDMOS or HVFET. When the HVFET or LDMOS is in an ON mode, a drift current flows between source and drain. In the OFF mode, the drift region is depleted of carriers.

Unfortunately, by known methods forming the layers of the first conductivity type disposed at different vertical depths, a high energy implanter is necessary. High energy implanters (in the MeV energy range) are comparably expensive and are not commonly available in a semiconductor production line. Moreover, implantation damage due to the high energy ions may result in reliability issues and also masking of high-energy ions becomes increasingly difficult.

There is a need, therefore, for a method of fabricating power semiconductor devices that overcomes at least the shortcomings and disadvantages of the known methods described.

### SUMMARY

In accordance with an illustrative embodiment, a method of manufacturing an extended drain of a high voltage field-effect (HVFET or LDMOS) transistor includes: a) implanting a first dopant in a substrate of a first conductivity type to form a first region of a second conductivity type in the substrate; b) implanting a second dopant into the substrate at a surface to form a second region of the first conductivity type, wherein the first region and the second region form a pn junction; c) forming an epitaxial layer of the first conductivity type on the surface layer, wherein the surface layer is substantially covered by the first epitaxial layer; and implanting a third dopant of the second conductivity type in the epitaxial layer to form a third region of the second conductivity type.

In accordance with another illustrative embodiment, a high voltage metal oxide semiconductor device includes a substrate of a first conductivity type and a source region of a second conductivity type. The device also includes: a channel region having a body-region of the first conductivity type disposed around the source region; a drain region of the second conductivity type; a first region of the second conductivity type disposed in the substrate; a second region of the first conductivity type substantially at a surface, wherein the first region and the second region form a pn junction. An epitaxial layer of the first conductivity type is disposed over the substrate having a third region of the second conductivity type therein; and an extended drain extends between the body and the drain region, wherein the first, second and third regions extend between the drain and the source.

### BRIEF DESCRIPTION OF THE DRAWINGS

The representative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIGS. 1a-1b are schematic cross-sectional views illustrating a method of fabricating a semiconductor device in accordance with a representative embodiment.

FIG. 2 is a cross-sectional view of an LDMOSFET having an extended drain in accordance with a representative embodiment.

FIG. 3 is a cross-sectional view of the device of FIG. 2, having a locally reduced (diluted) doping in the extended drain in accordance with a representative embodiment.

FIG. 4 is a graphical representation of simulated current flow as a function of depth through the LDMOS transistor as shown in FIG. 3.

FIG. 5 shows a simulated breakdown voltage V_{BD} of an LDMOSFET in accordance with an illustrative embodiment as shown in FIG. 3.

FIG. 6 is a schematic cross-section view illustrating a sequence of fabricating a semiconductor device with triple-path extended drain by a method in accordance with another representative embodiment.

FIG. 7 is a cross-sectional view of a triple-path LDMOS device in accordance with a representative embodiment and formed by the method of FIG. 6.

FIG. 8 is a cross-section of the device of FIG. 7 having locally reduced doping in accordance with a representative embodiment.

FIG. 9 is a graphical representation of simulated dopant concentration as a function of depth in the triple-path LDMOS of FIG. 8.

FIG. 10 is a graphical representation of simulated current flow in the triple path LDMOS as a function of depth and in accordance with a representative embodiment.

FIG. 11 is a graphical representation of the simulation of the corresponding breakdown voltage in accordance with a representative embodiment.

FIGS. 12a and 12b are cross-sectional views of a triple-path LDMOST, which is arranged for fast switching, in accordance with a representative embodiment.

### DETAILED DESCRIPTION

In the following detailed description, for purposes of explanation and not limitation, specific details are set forth in order to provide a thorough understanding of example embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of apparati, devices, materials and methods known to one of ordinary skill in the art may be omitted so as to not obscure the description of the example embodiments. Such apparati, devices, methods and materials are clearly within the scope of the present teachings.

The methods of representative embodiments described herein, are not limited to Si substrates; and are applicable to other semiconductor materials including, but not limited to: SiC, Ge, SiGe, InP, GaAs, GaN. In general, the RESURF principle of the present teachings may be applied to the formation of pn junctions in a semiconductor substrate.

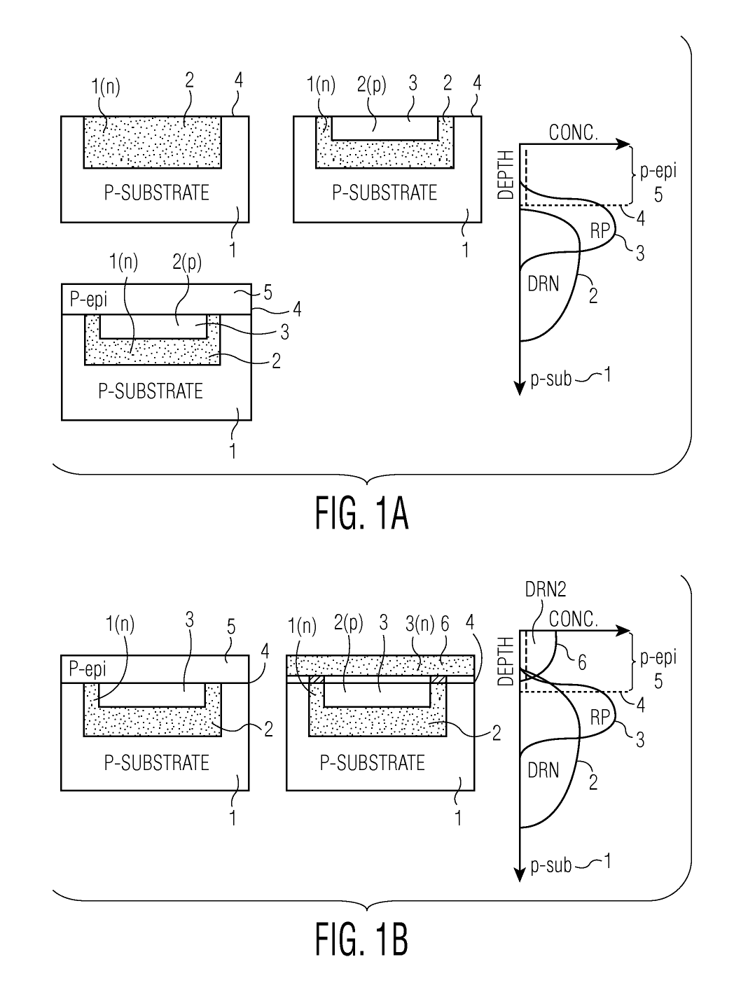

FIG. 1a illustrates a sequence of fabricating the extended drain for a HV semiconductor device by a method in accordance with a representative embodiment. The method is described in a sequence A, B, C in FIG. 1a. Illustratively, the resultant device is a High-Voltage Lateral MOSFET (HVFET) or Lateral Double-diffused MOS (LDMOS) transistor. In an LDMOS, the source is surrounded by a body region, both self-aligned to a (polycrystalline silicon) gate. However, as will be appreciated by one of ordinary skill in the art, the methods of representative embodiments, and their attendant benefits are applicable to a variety of semiconductor processing sequences and devices. Notably, the formation of the deep Resurf N (DRN) and Resurf P layer (RP) with on top a p-type epitaxial layer with subsequent n-type implantation (DRN2) can be advantageously used in the manufacture of many semiconductor devices.

Initially, a high-ohmic p-type substrate 1, which is illustratively Si is mask implanted with n-type dopant atoms to form a first region 2. In this example phosphorous (P) atoms are used with an implantation-energy of approximately 100 keV and a dose of approximately 6×10¹² at/cm². Next, a high temperature diffusion step is carried out to drive the n-type dopant deeper into the p-type substrate 1. This sequence forms a comparatively deep n-type region, which may be referred to herein as a Deep Resurf n, or DRN, and is labeled as such in the doping profile in FIG. 1a. Illustratively, the high temperature dopant diffusion sequence is carried out of approximately 9 hours (540 min.) and at a temperature of approximately 1150° C.

FIG. 1a (‘B’) illustrates an implant sequence according to a representative embodiment. A second region 3 is formed by masked implanting a p-type dopant such as Boron (B) or Indium (In), into a surface 4 of the substrate 1. Illustratively, B-dopant atoms are implanted at an energy of approximately 100 keV to approximately 180 keV and a dose of approximately 6×10¹² at/cm². Thus, a p-type layer substantially at the surface 4 is formed. Optionally, the p-type dopant atoms can be diffused, or activated during epitaxial growth in a subsequent step. The p-type second region 3 is indicated here as Resurf p, or RP, in the doping profile.

FIG. 1a (‘C’) illustrates the epitaxial growth of a p-type Si layer 5 having a thickness of approximately 2 μm to approximately 4 μm over the surface 4. Illustratively, the layer 5 is grown at approximately 1150° C. As described more fully herein, the p-type epilayer 5 may be the first epilayer in a multilayer stack formed by repeating the growth and doping sequences of the representative embodiment described in connection to FIGS. 1a and 1b.

Subsequent to being grown, the epilayer 5 is implanted (illustratively without a mask) with P-atoms at an implant energy of approximately 100 keV to approximately 300 keV and a dose of approximately 1.4e12 at/cm². After implantation, the P-atoms are optionally diffused to provide a third region 6 (DRN2) with n-type dopant in FIG. 1a (‘D’).

Illustratively, the thickness of the epilayer 5 is less than 4.5 μm. By choosing the thickness of the epilayer to be not too thick, only a limited temperature budget is required for diffusing dopant atoms of opposite conductivity type into the first epitaxial layer for locally overdoping the dopant concentration in the epilayer, until the dopants intersect with the up-diffused dopant from the DRN-layer. The thinner the epilayer 5, the lower the thermal budget necessary for diffusing the dopant atoms in the epilayer 5, and the better the control over the dopant concentration in the epilayer 5. As already mentioned, a good control of the dopant concentration is beneficial in RESURF devices.

In representative embodiments, the growth of the first epitaxial layer 5 is carried out at a temperature below 150° C. The first epitaxial layer 5 is grown on a comparatively highly-doped surface layer of the first conductivity type. In order to restrict the segregation and/or evaporation of dopant atoms from the surface layer when starting the epitaxial growth process of the first epitaxial layer, the temperature is usefully below 1150° C. Alternative ways to reduce the segregation of dopant atoms (in particular Boron), is to ramp up the epitaxy reactor, and to omit all additional temperature steps usually done such as a H₂ bake or furnace anneal step. In order to form a layer at or close to the surface, the energy of the implantation of the second dopants is usefully below 350 keV.

In the representative embodiments, the first conductivity type is p-type. The use of a p-type substrate 1 in combination with a p-type epitaxial layer 5 facilitates electrically insulating n-type transistors. Here at the intersection of the DMOS body and the up-diffused RP-layer, which is normally inside the epitaxial layer, the p-type dope enhances the junction isolation, whereas the use of an n-type epitaxial layer of much higher dope-level and without the DRN2 implantation is counter-acting the device isolation. As is known, junction isolation is more easily fabricated and cheaper than deep trench isolation.

After complete processing the net doses in the DRN and RP layers are each approximately 2e12 at/cm², in the DRN2 layer approximately 1e12 at/cm². The sheet resistance of the third region (DRN2) after processing is approximately 6 kOhm/square. As will become clearer as the description continues, the forming of the epitaxial layer 5 of the first conductivity type allows for easier access in depth to other layers of the first conductivity type and to the substrate.

Beneficially, the second region 3 of the first conductivity type is formed by a relatively low-energy implantation at the surface 4 and followed by epitaxial growth of an epitaxial layer 5 of the same first conductivity type on that surface layer. The combination of an implantation at the surface 4 and epitaxial growth circumvents the need for a high-energy dopant implantation (e.g., several MeVs) to realize the extended drain structure. A reduction in cost per wafer is obtained. Moreover, by omitting a high-energy implantation in the MeV range, the method can be applied in wafer-fabrication/processing facilities (wafer-fabs) with comparatively routine modification; and beneficially avoids wafer damage and subsequent repair that is often required prior to further processing. This offers significant advantages in flexibility to manufacture semiconductor devices in different wafer-fabs all over the world. Moreover, as will be appreciated by one of ordinary skill in the art, device reliability can be improved by reducing, if not eliminating, implant damage.

In accordance with the representative embodiments, the dopant concentration in the epitaxial layer 5 is well controlled, and particularly well-controlled to comparatively low dopant concentrations useful in high-voltage RESURF devices. To this end, according to the present teachings, epitaxial layer 5 of the first conductivity type is implanted with a third dopant to form a third region 6 of the second conductivity type in the epitaxial layer 5, the third region forming with the second region a pn junction. Improved control of dopant concentration can be obtained by overdoping locally the relatively low dopant concentration of the epitaxial layer 5 (e.g., p-type) by means of implantation dopant (e.g. n-type). This method allows a comparatively tight control of dopant atoms in the various p-n layers used for RESURF purposes. RESURF is obtained when the p-n layers under reverse-bias voltage are fully depleted before premature internal breakdown occurs. The depletion region is dependent on the dopant concentration of both the p and n layers. As such, in order to obtain fully-depleted p-n layers without exceeding the critical value of the electric field for breakdown, a good control of the dopant concentration is beneficial.

In an advantageous embodiment of the method suitable for RESURF the first epitaxial layer 5 is comparatively high-ohmic. As such, during epitaxial growth a relatively low concentration of dopant atoms is incorporated. The high-ohmic epitaxial layer 5 may be used in combination with a well-controlled implantation of ions of opposite conductivity type and subsequent optional diffusion described above. Because the dopant concentration in the high-ohmic epitaxial layer is comparatively low, only low dopant levels are necessary to compensate. In particular, dopant concentrations below 5e16 at/cm³ can be easily obtained with a very good control by implantation. However, some doping of the epitaxial layer 5 is useful to provide device isolation and contact to body/substrate 1.

As described more fully herein, the formation of alternating p-n layers by surface implantation combined with epitaxial growth and subsequently local overdoping of the epitaxial layer with a dopant of opposite conductivity type may be repeated one or more times. A plurality of stacked p-n layers may be formed on the substrate in this way. By applying these stacked p-n layers in the extended drain of a HVFET, the advantages are significant: by increasing the number of layers of the second type, the ON-resistance (Ron) is reduced at only slightly increased processing cost.

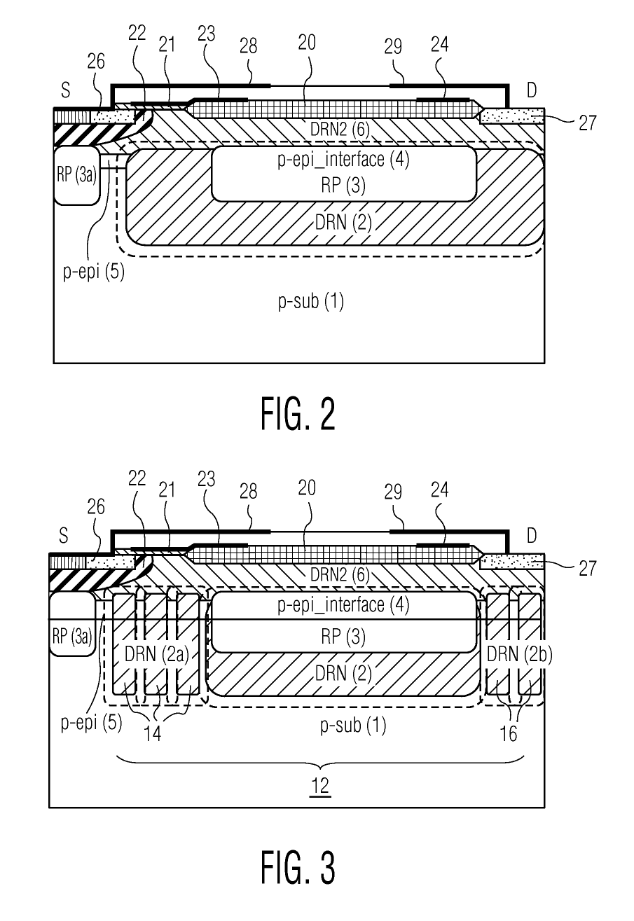

FIG. 2 is a cross-sectional view of an LDMOSFET in accordance with a representative embodiment and having an extended drain on substrate 1, which is illustratively p-type. The LDMOSFET includes two n-type drift current paths (DRN) 2, 6 (DRN2), and intermediate layer 3 (RP), which is illustratively p-type, between the source (S) and the drain (D).

After forming of the alternating pn layers described in connection with FIG. 1, a known semiconductor processing to realize the HV-MOSFET processing follows. In representative embodiments, a field-oxide (FOX) 20 having a thickness of approximately 1.0 μm is formed, such as by local oxidation of silicon (LOCOS). A gate-oxide 21 and an n+ doped poly-silicon gate 22 with field-plate at the source-side 23 are also formed by known methods and characteristics for the desired application. Optionally a field plate is formed at the drain-side 24.

Next, a p-type body and lateral channel-region 25 (usefully a double-diffused MOS (DMOS) type, self-aligned to the poly-silicon gate 22) are formed by implantation and subsequent diffusion. Next are applied an n+ source 26, usefully self-aligned to the poly-silicon gate, and an n+ drain 27, usefully self-aligned to the FOX 20. An intermetallic dielectric layer is the deposited by TEOS or LTO to a thickness of approximately 1.0 μm, followed by opening contact-windows and deposition and etching of metallization for source with a field-plate 28, for a gate (not shown) and for drain with a field-plate 29. Usefully, this is covered by a dielectric scratch protection also enhancing the HV stabilization, in which openings for bond-pads are made.

In the ON-state, electrons flow from the source and MOS-channel to the drain through the two n-channel drift regions (Dual path). The total ON-state resistance (Rₒₙ) of the HV MOSFET now consists of the two resistances in parallel, which as will be appreciated by one of ordinary skill in the art, significantly lowers the ON resistance of the device. HV-DMOS transistors are used as switches in HV power supplies. The switches allow power conversion at approximately 100 kHz to approximately 500 kHz. For those power switches the ON-resistance (Ron) and Breakdown voltage (BV_{dS}) values are very important parameters.

The epitaxial layer 5 initially was p-type after epitaxial growth. After diffusion of the P atoms, a third region of n-type (DRN2) 6 is formed, which forms with the second region (RP) a pn junction. Due to thermal processing such as the diffusion of the body after epitaxy, the various layers in the drift extension have some overlap, related with compensation of dope. Some small dopant compensation takes place between DRN2 and RP layers, typically approximately 25%, depending on the thickness of the epitaxial layer 5. The n-type P atoms of the first region (DRN) compensate for a certain (large) amount the p-type concentration of the second region (RP). In this example approximately 65% of the dopant concentration of the DRN and RP layers is compensated. The dopant concentration in the p-n layers is critical when used for RESURF. So the implantation dose of both the B as well as the P is critical in combination with the thermal budget.

The use of epitaxial growth of the first conductivity type beneficially isolates the device under the source to the body region. Here at the intersection of the DMOS body 25 and the up-diffused RP-layer 3a, which is normally inside the epitaxial layer, the p-type dope enhances the junction isolation, whereas the use of an n-type epitaxial layer of much higher dope-level and without the DRN2 implantation is counter-acting the device isolation. With an epilayer 4 of the second conductivity type together with a shallow body-diffusion 25, the device isolation with the up-diffused RP layer 3a could prove problematic. The same applies if more alternating layers are used in representative embodiments described herein. On the other hand the up-diffused DRN layer 2 must intersect sufficiently with DRN2 6 for the on-state current. This sets rather tight limits to the thickness of the epitaxial layer. With these restrictions, the HV LDMOST of FIG. 2 with an extended drain comprising a first region N layer (DRN), a second region P layer (RP) with on top a p-type epitaxial layer and an n-layer (DRN2) can be fabricated by the method of a representative embodiment described herein.

FIG. 3 is a cross-sectional view of an HV-MOSFET in accordance with a representative embodiment. The HV-MOSFET shares many features with those described in previously described representative embodiments. Notably, FIG. 3 shows a cross-section of the device of FIG. 2 having reduced doping in the first region on locations without a second region, close to the source and probably usefully also at the drain. A dashed line indicates the out-diffusion edge. The n-links, DRN-2a and DRN-2b, at the source and drain side are designed with reduced dopant concentration obtained by mask-patterning, as is indicated in FIG. 3. This is useful because the doping of both n-regions without a compensating P-region is comparatively high, which may invoke a local premature breakdown.

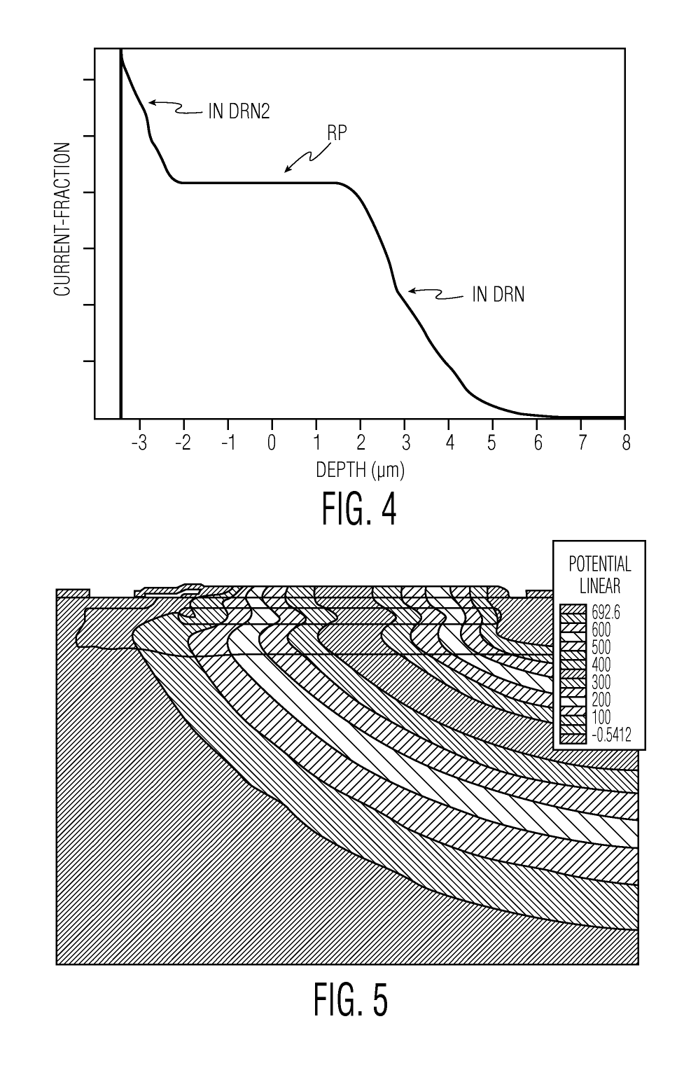

FIG. 4 is a graphical representation of simulated current flow as a function of depth through the LDMOS transistor as shown in FIG. 3. The simulated current flow-lines are calculated at V_{ds}=0.1 V. The current-flow through the LDMOS depends on ratio of the sheet resistances of the various layers. The calculated sheet resistance for the DRN2 is illustratively 6.20 kOhm/sq and for the DRN layer is illustratively 3.37 kOhm/sq. As a consequence approximately 35% of the current flows through the DRN2 and 65% through the DRN layer. For a LOCOS length (or drift length) of 55 μm, a typical value of Ron*A=9 Ohm.mm² can be obtained, where A is the active area of the device.

FIG. 5 shows a simulated breakdown voltage V_{BD} of 692 V for a drift length of 55 μm. The simulated LDMOS device is therefore very suitable for high voltage applications. By increasing the drift length (e.g. to 65 em), the breakdown voltage is increased. A tradeoff is realized in an increase in On-resistance, resulting in Ron*A=12.4 Ohm.mm².

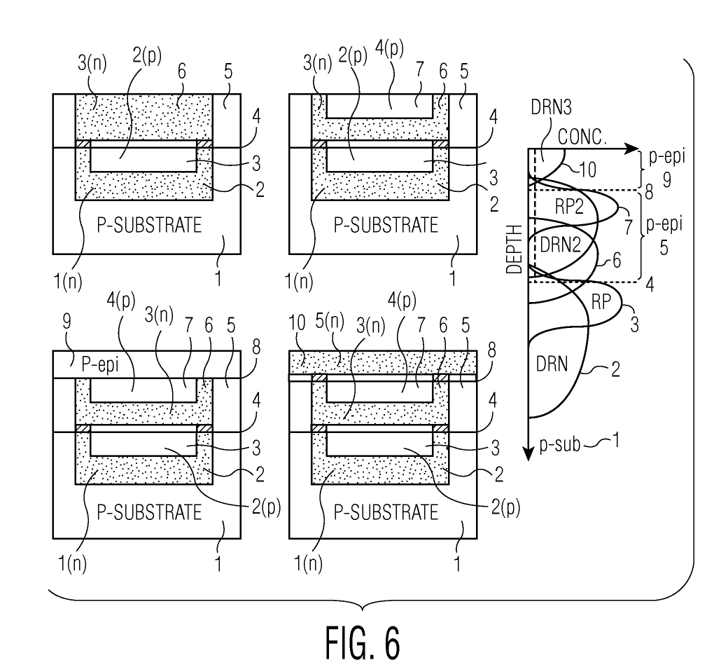

FIG. 6 illustrates a sequence of fabricating the extended drain of an HV semiconductor device by a method in accordance with another representative embodiment. The method is described in a sequence D,E,F,G in FIG. 6 and is shown in cross-sectional view. The method results in an extended-drain drift-region with three parallel paths. Moreover, the method includes sequences, materials and fabrication parameters described previously in connection with FIGS. 1a-5. Such common features are omitted in order to avoid obscuring the description of the present embodiments.

In a high-ohmic p-substrate 1 a first n-type region 2 (DRN) and second p-type region 3 (RP) are formed (‘D’). Next, a now slightly thicker p-type epitaxy 5 is grown on interface 4 and implanted with dopants using a mask and forming a third n-type region 6 (DRN2), which is optionally diffused. A fourth region 7 of p-type (RP2) is implanted using a mask substantially at the surface (i.e., at or close to the surface). A second p-type epitaxial layer 9 is grown over an interface 8 (‘F’). This epilayer 9 is implanted with usefully a blanket n-type layer 10 (without a mask) thereby forming a fifth region (DRN3), which is n-type (‘G’).

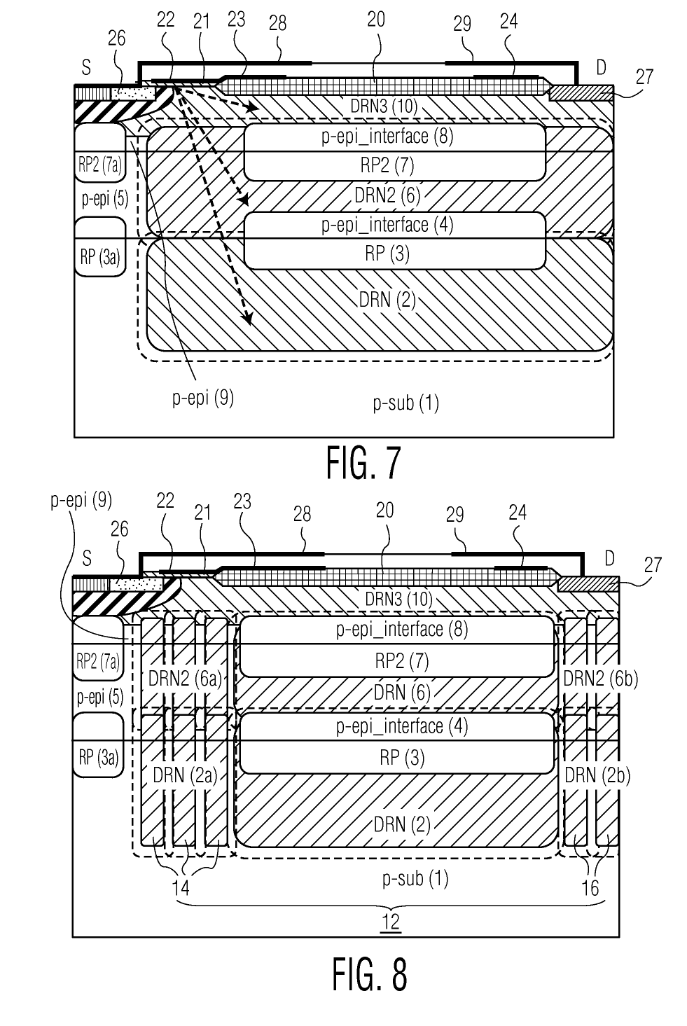

FIG. 7 is a cross-sectional view of a triple-path LDMOS device in accordance with a representative embodiment and formed by the method of FIG. 6. The use of p-type epitaxy facilitates connection between RP-3a, RP2-7a and body (25) and substrate (1) for appropriate device isolation and grounding of the alternating p-type layers. In the ON-state three n-type drift current paths are provided in parallel (DRN, DRN2 and DRN3), where the conduction of each DRN and DRN2 is approximately twice that of DRN3. The three n-type regions are separated by two p-type regions (RP and RP2).

FIG. 8 shows a cross-section of the device of FIG. 7 having at a location of a vertical link between the n-layers at source and drain, without compensating p-layers, some dilution of the n-dose by mask-pattern, as is indicated by DRN-2a, DRN-2b, DRN2-6a, DRN2-6b as shown. At least close to the source this is required, in order to prevent a local premature breakdown. A dashed line indicates the out-diffusion edge.

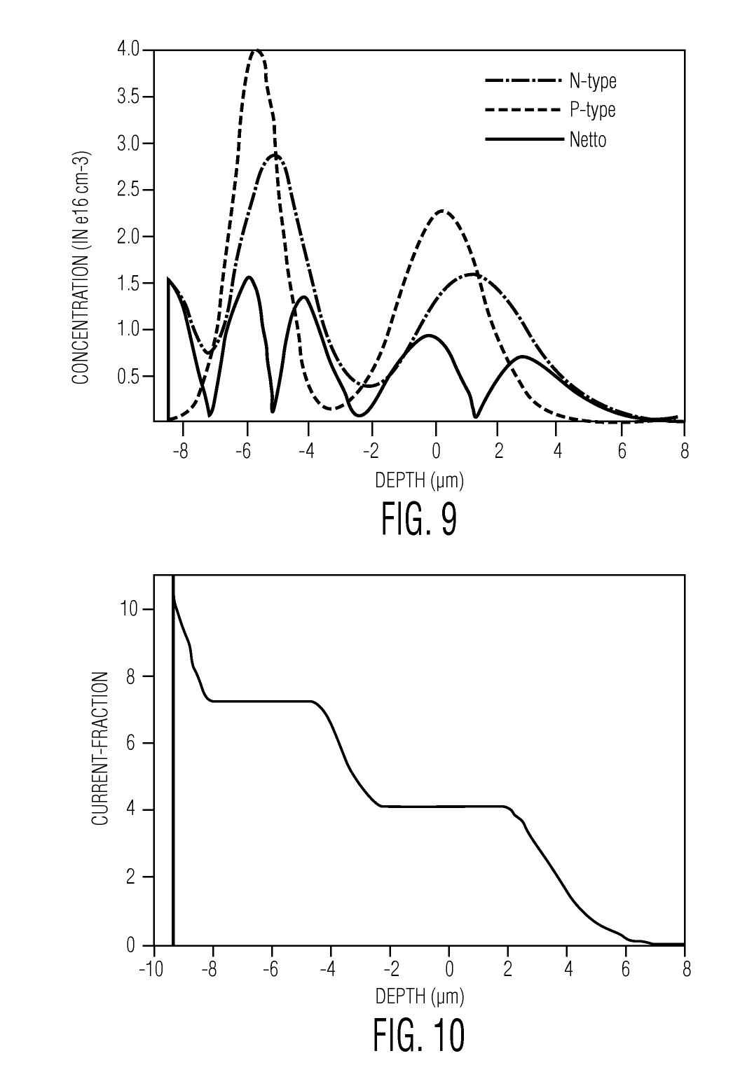

FIG. 9 is a graphical representation of simulated dopant concentration as a function of depth in the triple-path LDMOS of FIG. 8. The dotted line shows the active Phosphorus concentration (n-type) and the dashed line indicates the active Boron concentration (p-type). The drawn line refers to the net dopant concentration as a function of depth.

FIG. 10 is a graphical representation of simulated current flow in the triple path LDMOS as a function of depth. A suitable current distribution is shown at Vds=0.1V. The specific sheet-resistances of the n-type layers are: DRN3=6 kOhm/sq, DRN2=3.5 kOhm/sq and DRN=3.62 k/sq. The current flowing through these n-type layers is in accordance with the values of the sheet resistances. The percentage of current flowing through the DRN3 is approximately 20%, through DRN2 approximately 40% and through the DRN approximately 40%. The On-resistance for the triple path LDMOST was extracted at Vds=0.1V, Vgs=14V to be Ron*A=5.7 Ohm.mm².

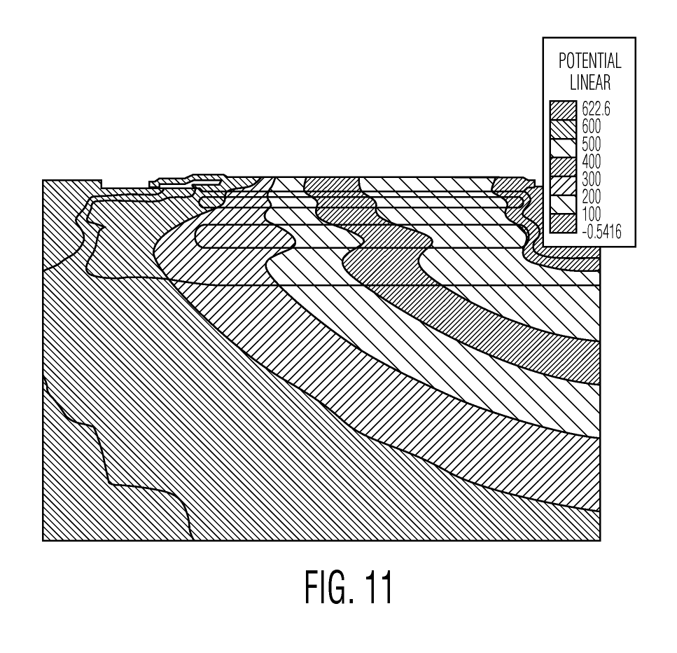

FIG. 11 is a graphical representation of the simulation of the corresponding breakdown voltage. For a drift-length of approximately 55 μm, the calculated breakdown voltage is approximately 622V. A further increase in breakdown voltage is possible, by ensuring that the electric field lines in DRN do not shift too fast to the drain. The DRN-implantation dose, which is illustratively 6.5e12 at/cm² should therefore be slightly adapted for obtaining a breakdown voltage V_{bds} of approximately 720 V.

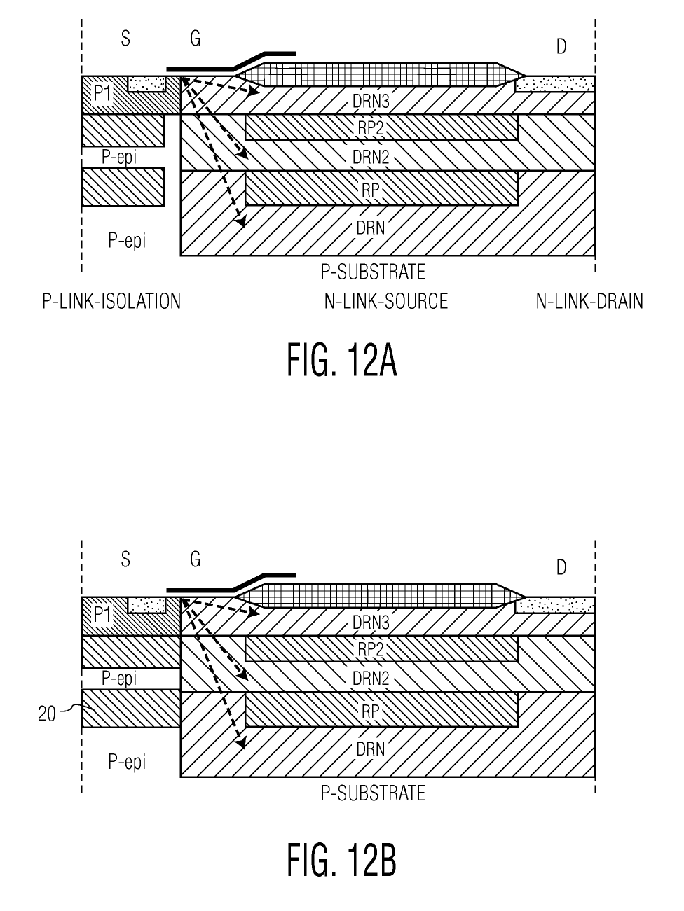

FIGS. 12a and 12b are cross-sectional views of a triple-path LDMOST, which is arranged for fast switching, in accordance with a representative embodiment. The triple path LDMOST shown in FIG. 12a has an interdigitated finger structure with local contacts between the various layers. The “N-link-at Source” comprises diluted n-regions in the DRN and DRN2 layers close to the source as is shown in FIG. 8, where the p-layer is interrupted. The N-Link-at-Drain as indicated may also need some dilution, since it also has no compensation by a p-type layer. The P-Link-Isolation indicates the situation for device isolation under the body. In FIG. 12a the P-layers are shown as floating. However this is not favorable for good Resurf operation of the drain extension, since now at rising V_{dS} the layers must be charged by punch-through; at falling V_{dS} these p-layers may remain charged, which leads to a higher on-state resistance.

As shown in FIG. 12b, over a width of the fingers locally the p-layers RP/RP2 are continued through the “N-Link-at-Source.” As such, a local contact between the RP/RP2 layers in the drift region and the Body/substrate is made. The local contact enables a more rapid charge and discharge at fast switching. The local contact reduces the effective Width by approximately 1% to approximately 2% only.

Further improved embodiments of the LDMOST can be obtained by including one or more of the measures indicated below. Notably, further description of the noted Source and Drain Fingertips may be found in the related application filed concurrently.

At the Source Fingertips the drift region may be longer and the field-plate to source ‘stretched.’ Moreover, the n-layers (such as DRN and DRN2) may be somewhat withdrawn and/or mask-diluted (by having only locally openings for the implantation) as described in the related application filed concurrently. Furthermore, the p-layers may remain present since the source is not active here, in order to compensate for the effect of junction curvature.

Also at the Drain Fingertips the drift region may be longer and the field-plate to drain ‘stretched’. The p-layers (such as RP and RP2) may be slightly withdrawn and/or mask-diluted (by having only locally openings for the implantation) as described in the related application filed concurrently. Furthermore, the drain fingertips may have no source thereabout in order to prevent a concentration of current in this region and to compensate for the effect of junction curvature.

As noted previously, the methods of the present teachings can be combined with the manufacturing of other transistors or devices on an integrated circuit. The LDMOSTs as described above can be combined with a HV-NJFET, with CMOS circuitry and/or with a HV-PMOS. Small modifications to the LDMOST might be desirable. For example, at the Drain fingertip a HV-NJFET can be included, which is particularly useful for providing a start-up current to a low voltage (LV) control section or chip. It is also possible to integrate CMOS circuitry. In this case the body region surrounding the source might be replaced by a P-well implanted and diffused before the Poly-gate is applied, which P-well now also can be used for LV NMOS and CMOS.

Also an integrated HV-PMOS device is possible. This might be useful for example for sensing an isolated output (secondary) at the non-isolated primary (switching) side.

In connection with illustrative embodiments, high voltage semiconductor devices and methods of fabricating the devices are described. One of ordinary skill in the art appreciates that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A method of manufacturing an extended drain of a high voltage field-effect (HVFET) transistor, the method comprising:
a) implanting a first dopant in a substrate of a first conductivity type to form a first region of a second conductivity type in the substrate;
b) implanting a second dopant into the substrate to form a second region of the first conductivity type, wherein the first region and the second region form a pn junction;
c) forming an epitaxial layer of the first conductivity type on the surface layer, wherein the surface layer is substantially covered by the first epitaxial layer; and
d) implanting a third dopant of the second conductivity type in the epitaxial layer to form a third region of the second conductivity type.

2. A method as claimed in claim 1, wherein the first region is diffused before the second region is implanted.

3. A method as claimed in claim 1, further comprising repeating b), c) and d) one or more times to form a plurality of stacked pn junctions on the substrate.

4. A method as claimed in claim 3, the method further comprising: diffusing the dopants prior to repeating b), c) and d).

5. A method as claimed in claim 1, wherein in that the first conductivity type is p-type and the second conductivity is n-type.

6. A method as claimed in claim 1, wherein the epitaxial layer has a thickness of less than approximately 4.5 μm.

7. A method as claimed in claim 6, wherein the epitaxial layer is grown at a temperature below approximately 1150° C.

8. A method as claimed in claim 1, wherein an energy of the implanting of the dopants is less than approximately 350 keV.

9. A method as claimed in claim 1, further comprising, after forming the second region, diffusing the second dopant.

10. A method as claimed in claim 1, further comprising during the forming of the epitaxial layer, activating the second dopant.

11. A method as claimed in claim 1, wherein a dose of the first and the second implantation is between approximately 4e12 cm⁻² and approximately 9e12 cm⁻², and a dose of the third implantation between approximately 1e12 cm⁻² and approximately 2e12 cm² .

12. A method as claimed in claim 1, wherein the substrate is one of: Si, SiC, Ge, SiGe, InP, GaAs, GaN.

13. A high voltage metal oxide semiconductor device, comprising:
a substrate of a first conductivity type;
a source region of a second conductivity type;
a channel region having a body-region of the first conductivity type disposed around the source region;
a drain region of the second conductivity type;
a first region of the second conductivity type disposed in the substrate;
a second region of the first conductivity type substantially at a surface, wherein the first region and the second region form a pn junction;
an epitaxial layer of the first conductivity type disposed over the substrate having a third region of the second conductivity type therein; and
an extended drain extending between the body and the drain region, wherein the first, second and third regions extend between the drain and the source.

14. A device as claimed in claim 13, wherein the source region is substantially surrounded by a body region and a local connection is provided between the second region and the body region and the epitaxial layer and the substrate.

15. A device as claimed in claim 13, further comprising an interdigitated structure with source and drain finger tips.

16. A device as claimed in claim 13, wherein the extended drain further comprises a plurality of alternating p-type and n-type regions.

17. A device as claimed in claim 13, wherein the first conductivity type is p-type and the second conductivity type is n-type.

18. A device as claimed in claim 16, wherein the plurality of regions includes at least one epitaxial layer of the first conductivity type.

19. A device as claimed in claim 13, wherein a doping concentration of the first and the second regions is between approximately 4e12 cm⁻² and approximately 9e12 cm⁻², and a doping concentration of the third region between approximately 1e12 cm⁻² and approximately 2e12 cm⁻².

20. A device as claimed in claim 13, wherein the device is a power device, which further comprises an interdigitated finger structure a local connection is provided between the body region and the second region.

21. A device as claimed in claim 13, wherein the substrate is one of: SiC, Ge, SiGe, InP, GaAs, GaN.

22. A device as claimed in claim 13, wherein an intersection of the body-region and the second region is within the epitaxial layer.

23. A device as in claim 13, wherein the second region is locally interrupted adjacent to the source and the first region is located adjacent to the source.

24. A device as in claim 13, wherein the drift-length and the related field-plate are enlarged at the finger-tips of drain and source 25. A device as in claim 16, further comprising another epitaxial layer of the first conductivity applied on a lower deep region of the second conductivity type applied before implanting a next region of the first conductivity type, wherein this epitaxial layer restricts the required diffusion depth of the lower deep region of the second conductivity type.
